(19) United States
(12) Patent Application Publication
(10) Pub. No.: US 2026/0009872 A1
(43) Pub. Date: Jan. 8, 2026

(54) Electron Magnetic Resonance Sample Heating

(71) Applicant: Quantum Valley Investment Fund LP, Waterloo (CA)

(72) Inventors: Hamidreza Mohebbi, Waterloo, CA (US); Troy W. Borneman, Waterloo, CA (US); Donald Edward Carkner, Waterloo, CA (US); Andrew Boorn, Waterloo, CA (US)

(73) Assignee: Quantum Valley Investment Fund LP, Wterloo (CA)

(21) Appl. No.: 19/324,622

(22) Filed: Sep. 10, 2025

Related U.S. Application Data
(63) Continuation of application No. PCT/CA2024/050350, filed on Mar. 22, 2024.
(60) Provisional application No. 63/492,084, filed on Mar. 24, 2023.

(51) Int. Cl. G01R 33/31

(52) U.S. Cl. CPC G01R 33/31

(57) ABSTRACT

In a general aspect, an electron magnetic resonance apparatus includes a resonator that resides in a cryogenic environment in a primary magnetic field. A sample holder in the cryogenic environment is maintained in a spaced relationship with the resonator. The sample holder includes a sample container. A sample heating device is positioned so that the sample container is thermally coupled to the sample heating device, and the sample heating device controls a temperature of the sample to be in a temperature range that is above an operating temperature of the resonator.

### CROSS-REFERENCE TO RELATED APPLICATIONS

This application claims priority to, and incorporates by reference the disclosure of U.S. Provisional Patent Application No. 63/492,084, filed on Mar. 24, 2023 and titled ELECTRON PARAMAGNETIC RESONANCE (EPR) SAMPLE HEATING.

### BACKGROUND

The following description relates to heating samples in electron magnetic resonance systems.

Electron magnetic resonance systems are used to study various types of samples and phenomena. A resonator manipulates the spins in a sample by producing a magnetic field at or near the spins' resonance frequencies. In some cases, the resonator detects the spins based on a voltage induced by the precessing spins.

### DESCRIPTION OF DRAWINGS

FIG. 1A is a schematic diagram of an example electron magnetic resonance system;

FIG. 1B is a block diagram of an example electron magnetic resonance system having a sample heater;

FIG. 2 is a top view of an example sample holder for use in an electron magnetic resonance system illustrating a sample heater and a resonator;

FIG. 3 is a perspective view of a sample holder and an example sample heater with a tapered filament showing their placement on a resonator;

FIG. 4 is a perspective view of a sample holder and an example sample heater with a transverse meandered line filament showing their placement on a resonator;

FIG. 5 shows an example tapered heating filament and an example transverse meandered line heating filament;

FIG. 6A is a plan view of an example longitudinal meandered line filament;

FIG. 6B is a plan view of an example transverse meandered line filament;

FIG. 6C is a plan view of an example sample heater having an array of tapered filaments;

FIG. 7A is a cross-sectional view of an example resonator package;

FIG. 7B is a cross-sectional view of an example resonator package with a separate sample holder cover;

FIG. 8A is a perspective view of an example helical sample heater used with a prismatic sample holder;

FIG. 8B is a perspective view of an example helical sample heater used with a tubular sample holder;

FIG. 9 is a perspective view of an example sample holder illustrating the sample heater and the resonator;

FIG. 10 is a perspective view of an example sample holder illustrating an example electrical connection of the sample heater;

FIG. 11 is plot of electromagnetic simulations illustrating behavior of an example resonator in the presence of an example sample heater;

FIG. 12 is an electromagnetic simulation illustrating current density in an example sample heater;

FIG. 13 is a plot of a temperature profile along a line perpendicular to the sample holder plotted against current flowing through an example sample heater;

FIG. 14 is a plot of temperature rise of a sample versus current flowing through an example sample heater for varying lateral locations of the sample heater;

FIG. 15 is a temperature field overlay on a bottom surface ofa sample holder;

FIG. 16 is a temperature field overlay in an example sample container; and

FIG. 17 is a flow diagram of an example process for heating a sample.

### DETAILED DESCRIPTION

In some aspects of what is described, an electron magnetic resonance system includes a sample heater that can be used to elevate a temperature of an electron magnetic resonance sample above an operating temperature of a resonator. In some cases, the sample and the resonator are configured to interact with each other in a cryogenic operating environment while the sample is thermally insulated from the resonator, such that the sample and the resonator are maintained at distinct temperatures during operation. The resonator can be held at a lower temperature (e.g., to reduce or suppress thermal noise, to maintain a superconducting state of the resonator, or for other purposes) while the sample is held at a higher temperature (e.g., to reduce a thermal relaxation rate of the sample, to maintain a liquid state of the sample, or for other purposes).

The sample heater may include a heating filament that is electrically coupled to feedlines (e.g., a first feedline and a second feedline). The heating filament and the feedlines may be formed on a heating substrate. In other implementations, the heating filament and the feedlines may be spaced apart from the sample holder. The heating substrate, along with the heating filament and the feedlines, may be disposed on a sample holder. In some cases, the heating substrate also functions to seal a sample container of the sample holder. In implementations where the sample holder includes one or more capillary tubes, the heating substrate may be omitted. The sample heater may include additional components that operate to heat an electron magnetic resonance sample to a temperature above a resonator operating temperature. For example, a sample heating system may include a temperature control device, a temperature sensor, or a combination of these and other components. In some instances, the sample heater is disposed in a controlled environment near the resonator in the primary magnetic field of the electron magnetic resonance system.

In some implementations, the resonator operates at cryogenic temperatures, and the sample heater can raise a temperature of an electron magnetic resonance sample above the temperature of the resonator. For example, in certain electron paramagnetic resonance (EPR) systems, the resonator can be a microwave resonator that operates below a critical temperature of a superconducting material, and the sample can be held above the critical temperature during operation. The sample holder and the sample heater may be thermally insulated from the resonator. In some instances, the thermal insulation is provided by a vacuum or partial vacuum environment of the cryogenic system having, for example, a pressure of approximately 500 mTorr or less. In some instances, solid or fluid thermally insulating material may be disposed between the sample holder and the resonator. In some instances, the insulating material is a low-thermal-conductivity material such as, for example, aero-gel, Teflon, fiberglass, or any other insulating material. In systems that operate at cryogenic temperatures, the temperature of the resonator can be controlled to a desired operating temperature while the sample heater can be used to raise the temperature of the electron magnetic resonance sample to a desired sampling temperature that is above the operating temperature of the resonator. This can improve performance of the electron magnetic resonance system along with other advantages.

Aspects of the systems and techniques described here can be implemented in various types of electron magnetic resonance systems. For example, a sample heater may be implemented in an electron spin resonance (“ESR”) or electron paramagnetic resonance (“EPR”) system, or another type of electron magnetic resonance system. As another example, all or part of a heater apparatus may be deployed on a probe for an electron magnetic resonance system, or a sample heater can be deployed in a probeless electron magnetic resonance system. In some cases, a sample heater can be adapted to heat liquid samples, solid samples, liquid crystal samples, spin-labeled protein samples, other biological samples (e.g., blood samples, urine samples, saliva samples, etc.), or other types of samples to be measured or otherwise analyzed by an electron magnetic resonance system. As another example, a sample heater may be deployed with a resonator that operates in a cryogenic environment (e.g., at 77 K, 4 K, 300 milliKelvin, 10 milliKelvin, or other cryogenic temperatures below 273 K). In various implementations, the sample holder and the resonator are disposed in a partial vacuum environment for example, environments having a pressure of approximately 500 mTorr or less. The resonator can be, for example, a planar microstrip, a three-dimensional cavity, a coil, a coplanar waveguide, or another type of resonator for electron magnetic resonance systems. Additionally, the resonator could be, for example, a rectangular cavity resonator, a cylindrical cavity resonator, a dielectric resonator, a loop gap resonator, or any lumped element resonator.

In some cases, the systems and techniques presented here can be deployed in connection with various cryogenic systems, including for example, compact closed-cycle systems, open-cycle, liquid cryogen systems and others. In some cases, the systems and techniques presented here can be deployed in connection with various probes, including compact probe designs that may enable low-noise cryogenic receiver amplifiers to be used in a variety of configurations without disturbing sample changing methods. In some cases, the techniques and system described here can be deployed in connect with continuous wave (CW) magnetic resonance (e.g., using CW spectroscopy methodology), pulsed magnetic resonance (e.g., using pulsed spectroscopy methodology), or a combination of these and other MR regimes.

In some implementations, the systems and techniques described herein can provide technical advantages and improvement over existing technologies. Operating an electron magnetic resonance system at low temperature offers several benefits that enhance the quality of electron magnetic resonance measurements. First, in some cases, low temperature reduces the thermal noise contribution from electrical and microwave components, which are held at cryogenic temperatures, leading to an increase in the signal-to-noise ratio and sensitivity of the electron magnetic resonance system. Second, in some cases, the low temperature environment enables the use of superconducting resonators for exciting the sample's spin ensemble and measuring the electromagnetic signals generated by its response to the excitation. The ultra-low dissipation of superconducting resonators is reflected in their high quality factor (Q), which has a significant impact on spin-cavity interaction, which is useful for several applications. Finally, the polarization of the spin system—the relative difference between the spin's populations at the energy levels—is significantly increased at cryogenic temperature, resulting in a stronger electron magnetic resonance signal. However, it is important to note that the electron magnetic resonance samples are typically solid at low temperatures, making it impossible to test liquid samples or examine samples with free spins. Liquid samples typically become frozen and often crystallized at cryogenic temperatures, which does not accurately reflect their normal conditions.

On the other hand, some parameters of electron magnetic resonance samples, such as relaxation times T₁ and T₂ (or collectively phase memory decay time Tₘ instead of T₂), are temperature dependent and this can negatively affect electron magnetic resonance measurements at low temperatures. In particular, the spin-lattice relaxation process, denoted as T₁, is easily influenced by the lattice motion and phonon dynamics, therefore, it is more strongly temperature dependent than T₂ for most electron magnetic resonance samples. Typically, T₁ is longer at low temperatures, which reduces the saturation

$$S = \frac{1}{1 + {γ}^{2} {B}_{1}^{2} {T}_{1} {T}_{2}}$$

in continuous wave (CW) magnetic resonance. When s is less than 1, the amplitude of the CW magnetic resonance signal decreases and broadening of the signal may be observed as

$$Δ {B}_{pp} = \frac{4}{3 {γ}^{2} {T}_{2}^{2}} \times \frac{1}{s}$$

making CW measurement more difficult to conduct.

In pulsed magnetic resonance spectroscopy, T₁ characterizes the timescale for spin magnetization to return to its initial thermal equilibrium

$${M}_{z}^{0} .$$

This process is given by

$${M}_{z} ( t ) = {M}_{z}^{0} ( 1 - {e}^{- \frac{t}{{T}_{1}}} ) + {M}_{z} - ( {0}^{+} ) {e}^{- \frac{t}{{T}_{1}}} where {M}_{z} ( {0}^{+} )$$

is the longitudinal magnetization immediately after an RF pulse. Therefore, species at low temperatures with long T₁ values recover slowly, necessitating a prolonged repetition time for a signal averaging greater than 5T₁ signals.

Therefore, in some cases, improvements can be obtained by maintaining the resonator at a low temperature for optimal sensitivity and noise suppression, while keeping the temperature of the electron magnetic resonance sample significantly higher. This configuration results in shorter T₁ times, reduces thermal noise and enables the use of low-noise cryogenic electronics. It also leads to an enhancement in the continuous-wave (CW) spin signal and allows for rapid signal averaging making the overall electron magnetic resonance measurement more efficient.

Aspects of the systems and techniques described here can be adapted for various types of applications. For example, the systems and techniques described here may be used for structural biology measurements, for instance, to measure structural properties of proteins or protein complexes in a biological sample (e.g., a blood sample, a urine sample, or another type of biological sample). Such measurements can be useful in clinical applications, for example, diagnostics, treatments, pharmaceutical drug discovery/development and understanding the structure and function of membrane proteins, and other applications.

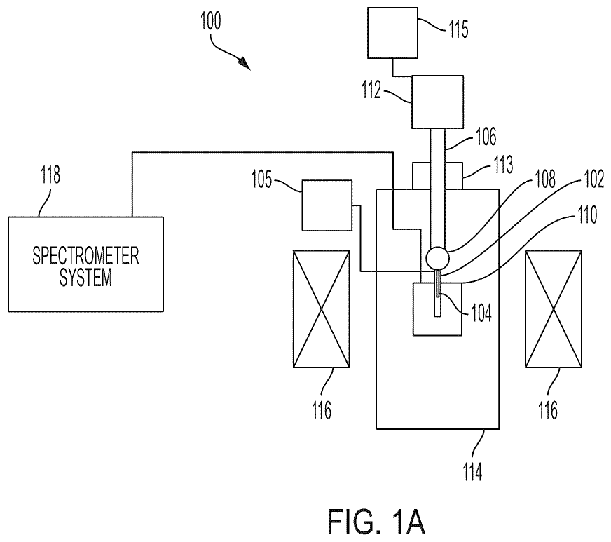

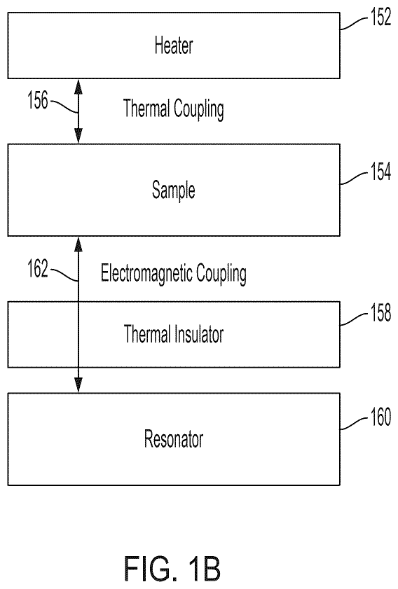

FIG. 1A is a schematic diagram of an example electron magnetic resonance system 100. In various implementations the electron magnetic resonance system 100 may be utilized, for example, in electron spin resonance (“ESR”) or electron paramagnetic resonance (“EPR”) spectroscopy, electron magnetic resonance imaging (“EMRI”, or other applications. The electron magnetic resonance system 100 includes a sample holder 102 that holds a sample that is thermally coupled to a sample heater 104. In various implementations, the sample holder 102 is constructed from a material that has favorable dielectric properties (e.g., low tangent loss) and that is suitable for cryogenic temperatures. In various implementations, the sample holder 102 may be constructed, for example, of quartz, sapphire, borosilicate glass, polystyrene, or other similar material. In the example shown in FIG. 1A, the sample holder 102 is coupled to a first end of a sample transfer device 106 via an attachment mechanism 108. The sample transfer device 106 can move the sample holder 102 and position the sample holder 102 relative to a resonator 110 in the primary magnetic field of the electron magnetic resonance system 100. In various implementations, the resonator 110 may be enclosed in a resonator housing or another type of resonator package.

In the example shown in FIG. 1A, the sample heater 104 is electrically coupled to a temperature controller 105. In various implementations, the temperature controller 105 may be an open-loop controller (non-feedback) or a closed-loop (feedback) controller. In implementations where the temperature controller 105 is an open-loop controller, the temperature controller 105 may supply an electrical current to the sample heater 104 that is correlated with a desired temperature of the sample heater 104. In implementations where the temperature controller 105 is a closed-loop controller, the temperature controller 105 may receive feedback information that indicates, for example, a temperature of the sample heater, a relaxation time (T₁ and T₂) of the electron magnetic resonance sample, other parameters, or combinations thereof. In various implementations, other devices such as, for example, a temperature sensor may be used in conjunction with the temperature controller 105 in implementations employing closed-loop temperature control. In various implementations, the electrical current supplied by the temperature controller 105 to the sample heater 104 may be direct current (DC), alternating current (AC), a sequence of current pulses, a periodic waveform such as square, sawtooth, triangle, or other type of current.

In the example shown in FIG. 1A, a second end of the sample transfer device 106 is coupled to an actuator 112. In operation, the actuator 112 drives movement of the sample transfer device 106 and may, in various implementations be, for example, a single-degree-of-freedom linear actuator that translates the sample transfer device 106 in a linear fashion along an axis of the sample transfer device 106. Examples of single-degree-of-freedom linear actuators include, for example, a mechanical linear actuator, an electro-mechanical linear actuator, a linear motor, a piezoelectric actuator, a twisted and coiled polymer (“TCP”) actuator, a hydraulic actuator, a pneumatic actuator, or other type of linear actuator. The actuator 112 is coupled to a position control system 115 that controls operation of the actuator. In various implementations, the position control system 115 may be, for example, an automated control system such as, for example, a CNC control system, a PID control system, or other type of controller. In some cases, the position control system 115 may include, or may be implemented as, software or firmware running on a computer system (e.g., a microprocessor or another type of data processing apparatus). In some instances, the control mechanism may be a manual control such as, for example, a caliper, micrometer or hand crank. This can be further enhanced by incorporating a laser indicator.

In the example shown in FIG. 1A, the resonator 110 and the sample holder 102 are disposed in a controlled environment that is cooled by the cooling system 114, while the second end of the of the sample transfer device 106 is disposed outside of a controlled environment. The sample transfer device 106 is introduced to the cooling system 114 via an insertion point 113. In various embodiments, the insertion point 113 can be or include a valve, a load lock system, or another type of component that provides environmental isolation. For example, in various implementations, the insertion point 113 may provide a vacuum-pressure environment or a low pressure gas seal between a controlled environment within the cooling system 114 and a room temperature environment. In various implementations, the vacuum-pressure environment may be milli-Torr pressure. In various implementations, the cooling system 114 maintains a cryogenic thermal environment for the resonator 110 and the sample holder 102. In some cases, the cooling system 114 can maintain a cryogenic temperature of the resonator 110 and the sample holder 102. In the example shown in FIG. 1A, the cooling system 114 resides in thermal contact with the resonator 110 and the sample holder 102. In some cases, the cooling system 114 cools to liquid helium temperatures (e.g., approximately 4 Kelvin), liquid nitrogen temperatures (e.g., approximately 77 Kelvin), or at another cryogenic temperature. In some cases, the cooling system 114 includes a cryogen-free (a “dry”) cryostat. In some cases, the cooling system 114 can be implemented with or without the use of liquid cryogens, for example, as a continuous flow helium or nitrogen cryostat (e.g., 4-300 Kelvin), as a variable temperature pulsed-tube refrigerator (e.g., 3.5-300 Kelvin), a pumped helium cryostat (e.g., 1-10 Kelvin), a helium-3 refrigerator (e.g., 250-400 milliKelvin), a dilution refrigerator (e.g., 5-100 milliKelvin), or another type of system or combination of systems. The resonator 110 and the sample holder 102 are both held at cryogenic temperatures. In some cases, the resonator 110 and the sample holder 102 are immersed in a cryogenic liquid or a cryogenic gas, and may be held in a vacuum-pressure or partial vacuum pressure environment during operation. In various implementations, the sample holder 102 and the resonator 110 are disposed in a partial vacuum environment of, for example, approximately 500 mTorr or less. In some cases, the sample holder 102, the resonator 110, or both are held at a higher temperature (e.g., room temperature, etc.).

In the example shown in FIG. 1A, a primary magnet system 116 generates a primary magnetic field that the resonator 110 and the sample holder 102 are exposed to during operation. In various implementations, the primary magnet system 116 may be located within the cooling system 114 or outside of the cooling system 114. The primary magnet system 116 generates a magnetic field in the controlled environment of the resonator 110 and the sample holder 102. The example primary magnet system 116 shown in FIG. 1A can be implemented as a superconducting solenoid, an electromagnet, a permanent magnet or another type of magnet that generates the primary magnetic field. In various implementations, the magnetic field is homogeneous over the volume of a sample region defined by the resonator 110. In various implementations, the sample region is a region that gives a desired filling factor for a particular application. In some instances, a gradient system generates one or more gradient fields that spatially vary over the sample volume. In some cases, the gradient system includes multiple independent gradient coils that can generate gradient fields that vary along different spatial dimensions of the sample region.

In the example shown in FIG. 1A, a spin ensemble in the sample region of the resonator 110 interacts with the resonator 110. The primary magnetic field generated by the primary magnet system 116 quantizes the spin states and sets the Larmnor frequency of the spin ensemble. Control of the spin magnetization can be achieved, for example, by a radio-frequency or microwave magnetic field generated by the resonator 110. In the example shown in FIG. 1A, the spin ensemble can be any collection of particles having non-zero spin that interact magnetically with the applied fields of the electron magnetic resonance system 100. For example, the spin ensemble can include electron spins or a combination of nuclear and electron spins. Examples of nuclear spins include hydrogen nuclei (¹H), carbon-13 nuclei (¹³C), and others. In some implementations (e.g. in an electron paramagnetic resonance (EPR) system), the spin ensemble is a collection of identical spin-½ free electron spins attached to an ensemble of large molecules.

In the example shown in FIG. 1A, the resonator 110 is electromagnetically coupled to a spectrometer system 118. In various implementations, the spectrometer system 118 acquires electron magnetic resonance data based on electron magnetic resonance signals generated by an interaction between the resonator 110 and electron magnetic resonance samples contained in the sample holder 102. Typically, the resonator 110 has one or more resonance frequencies and possibly other resonance frequencies or modes.

The example spectrometer system 118 can control the resonator 110 and possibly other components or subsystems in the electron magnetic resonance system 100 shown in FIG. 1A. The spectrometer system 118 is electromagnetically coupled to (e.g., by coaxial cables, waveguides, etc.) the resonator 110. For example, the spectrometer system 118 can be adapted to provide a voltage or current signal that drives the resonator 110; the spectrometer system 118 can also acquire a voltage or current signal from the resonator 110.

In some cases, the spectrometer system 118 includes or is connected with a controller, a waveform generator, an amplifier, a transmitter/receiver switch, a receiver, a signal processor, and possibly other components. A spectrometer system 118 can include additional or different features (e.g., a gradient waveform generator, and gradient electronics, etc.). In the example shown in FIG. 1A, the spectrometer system 118 is electromagnetically coupled to, and may operate based on inputs provided by, one or more external sources, for example, a computer system or another source.

In some aspects of operation, control signals are generated by the spectrometer system 118 and delivered to the resonator 110. In some instances, the control signal can be filtered, amplified, or processed prior to delivery to the resonator 110. In some instances, the control signal causes the resonator 110 to generate one or more control fields in the sample region of the resonator 110. For example, the resonator 110 may receive control signals and generate radio-frequency or microwave frequency control fields (e.g., drive fields) in response to the received magnetic resonance control signals. The drive frequency of the control fields can be tuned to the spins' resonance frequency, which is determined by the strength of the primary magnetic field and the gyromagnetic ratio of the spins. In some aspects of operation, electron magnetic resonance signals (e.g., electron spin signals) are received from the resonator 110 and processed (e.g., amplified, filtered, down-converted, etc.) by the spectrometer 118. In some instances, the electron magnetic resonance signals are processed, for example, to analyze properties of the sample.

In some cases, the spectrometer system 118 may operate in multiple modes of operation. In one mode of operation, the spectrometer system 118 generates control signals (e.g., radio frequency signals, microwave signals, etc.) that are delivered to the resonator 110 to control the spin system in the sample. In another mode of operation, the spectrometer system 118 acquires electron magnetic resonance signals from the resonator 110. The electron magnetic resonance signals can be processed (e.g., digitized) and provided to a computer system for analysis, display, storage, or another action. The computer system may include one or more digital electronic controllers, microprocessors or other types of data-processing apparatus. The computer system may include memory, processors, and may operate as a general-purpose computer, or the computer system may operate as an application-specific device.

FIG. 1B is a block diagram of an example electron magnetic resonance system 150 having a sample heater 152. The sample heater 152 is thermally coupled to a sample 154. Such thermal coupling is illustrated in FIG. 1B by arrow 156. In various implementations, the sample heater 152 may be, for example, the sample heater 104 illustrated in FIG. 1A. The sample 154 may be contained in a sample holder such as, for example, the sample holder 102 illustrated in FIG. 1A. In various implementations, the sample holder may have a prismatic geometry. In such implementations, the sample holder may include a cover that closes the sample holder. In some implementations, the sample heater 152 may be coupled to the cover. In other implementations, the sample heater 152 may be spaced apart from the sample holder. In still other implementations, the sample holder may include, for example one or more capillary tubes or other devices appropriate for containing the sample 154. During use, the sample 154 is disposed in a sample region of a resonator 160. In various implementations, the sample region is a region that gives a desired filling factor for a particular application. The resonator 160 may be, for example, the resonator 110 illustrated in FIG. 1A or another type of resonator. The resonator 160 interacts with the sample 154 via an electromagnetic coupling. Such an electromagnetic coupling is illustrated schematically by arrow 162. A thermal insulator 158 is disposed between the sample 154 and the resonator 160. In various implementations, the thermal insulator 158 may be, for example, a partial vacuum having a pressure of approximately 500 mTorr or less. In other embodiments, the thermal insulation 158 may be a material such as, for example, aero-gel, fiberglass, or other type of solid or fluid thermal insulation. During operation, the sample 154 and the resonator 160 are disposed in a cryogenic environment. The sample heater 152 functions to raise a temperature of the sample 154 to a desired temperature above the temperature of the resonator 160. The thermal insulation 158 limits thermal interaction between the resonator 160 and the sample heater 152 and prevents introduction of thermal noise and other performance degradation of the resonator 160 due to undesired temperature rise.

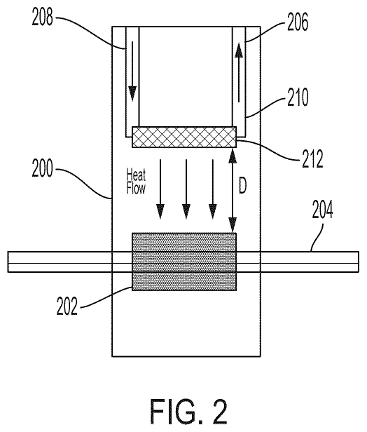

FIG. 2 is a top view of an example sample holder 200 for use in an electron magnetic resonance system. FIG. 2 illustrates an example sample heater 206 and a resonator 204. In various implementations, the sample holder 102 in FIG. 1A can be implemented as the sample holder 200 shown in FIG. 2. Similarly, the sample heater 206 and the resonator 204 in FIG. 2 may be, for example, the sample heater 104 and the resonator 110 discussed with respect to FIG. 1A. In various implementations, the sample holder 200 has a sample container 202 formed therein. In various implementations, the sample container 202 may be, for example, a void formed in the sample holder 200. In other implementations, the sample container 202 may include a plurality of microcapillaries or other structures that can hold a sample. In still other implementations, the sample container 202 may be an array of sample containers spaced along a length of the sample holder 200. During use, the sample container 202 is positioned in a sample region of the resonator 204. By way of example, the resonator 204 is illustrated as a planar microstripline resonator; however, in other implementations, other types of resonators could be utilized such as, for example, a three-dimensional cavity, a coil, a co-planar waveguide (CPW), or another type of resonator for electron magnetic resonance systems.

The sample heater 206 is positioned above the sample holder 200 such that the sample container 202 is thermally coupled to the sample heater 206. The sample heater includes a first feedline 208, a second feedline 210, and a heating filament 212 that is electrically coupled to the first feedline 208 and the second feedline 210. During operation, the first feedline 208 and the second feedline 210 are electrically coupled to the temperature controller 105 and provide electrical current to the heating filament 212.

The heating filament 212 converts electrical energy to heat energy. In various implementations, an electrical current of any type such as DC, AC, a sequence of pulses, periodic waveforms such as square, triangle, sawtooth, etc. passes through the heating filament 212 via the first feedline 208 and the second feedline 210 and generates heat due to the electrical resistance of the heating filament 212. In various implementations, the heating filament 212 may be made of highly resistive metals or ceramics such as, for example, tungsten, molybdenum, nichrome, kanthal, etc. The electric current is supplied to the heating filament 212 by the temperature controller 105 and is transferred to the heating filament 212 through the first feedline 208 and the second feedline 210. In order to reduce the overall circuit loss, the first feedline 208 and the second feedline 210 may be made of high conductivity materials such as, for example, copper, gold, etc.

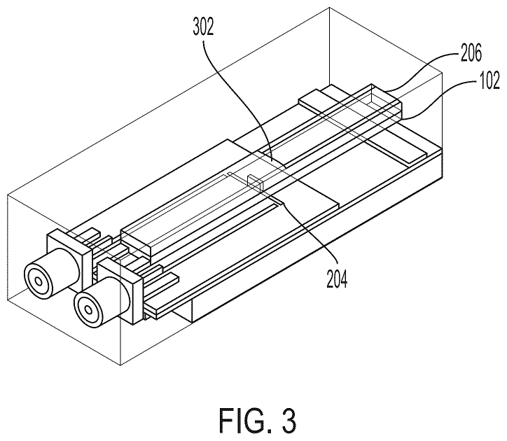

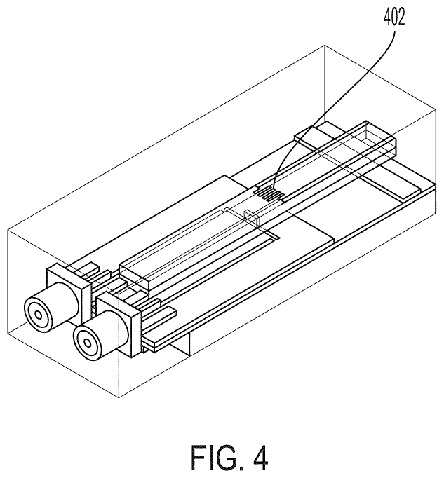

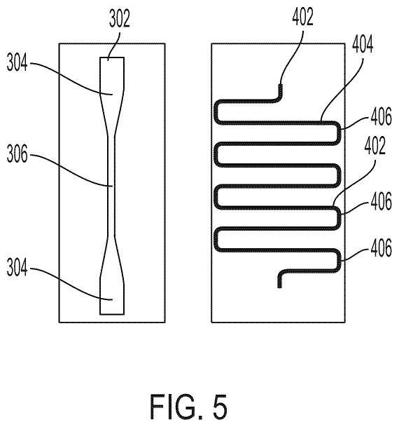

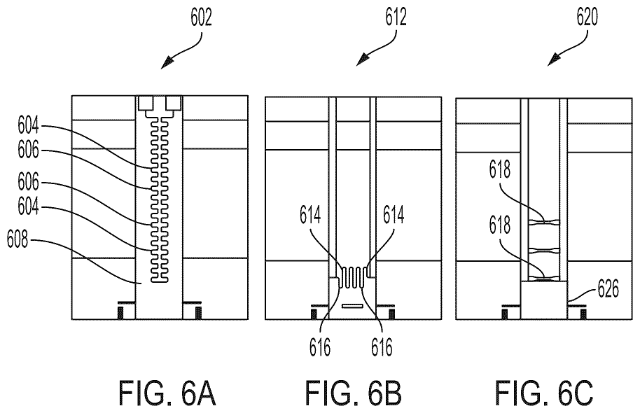

FIG. 3 is a perspective view of the example sample holder 200 and an example sample heater 206 with a tapered filament showing placement on the resonator 204. In various implementations, the heating filament 302 can be designed in a straight line, tapered line, meandered line, or other pattern, as illustrated in FIGS. 3-6B, and can be one single unit or an array of filament unit cells as illustrated in FIG. 6C. By way of example, FIG. 3 illustrates a heating filament 302 that has a tapered geometry. FIG. 4 illustrates another example heating filament 402 that is arranged in a transverse meandered line pattern. FIG. 5 presents a detailed the heating filament 302 alongside the heating filament 402 for comparison. The heating filament 302 shown in FIG. 3 includes end portions 304, which couple electrically to the first feedline 208 and the second feedline 210. A center portion 306 has a width that is narrower than the end portions 304 thereby increasing electrical resistance and generated heat in the region of the central portion 306. The heating filament 402 shown in FIG. 4 includes parallel segments 404, which are joined sequentially at opposite ends by perpendicular connecting segments 406, thereby giving the heating filament 402 a meandering shape. Such a shape increases an overall length of the heating filament 402, which increases electrical resistance and generated heat.

In one example, if the length, width and thickness of the heating filament 212 are 0.8 mm, 0.05 mm and 0.001 mm, respectively, and the heating filament 212 is made of molybdenum with electrical conductivity of σ=1.76×107 S/m, the resistance of the heating filament 212 would be R=0.9091Ω. Additionally, a meandered heating filament with a total length of 10 mm would have a resistance of R=11.3636Ω. These example calculations demonstrate the dependence of the resistance of the filament on its dimensions, shape, and 14, material. For comparison, a copper feedline with a conductivity of σ=5.8×107 S/m width of 0.5 mm, thickness of 0.001 mm, and length of 13.82 mm would have a resistance of R=0.4766Ω. As the source of the heat flow in the structure depends on the electrical power dissipated in the resistive filament through the relation P=RI², the amount of the electric loss and transferred heat can be controlled by adjusting a current source driving the filament circuit such as, for example, the temperature controller 105. In FIGS. 4-6C alternative designs for the heating filament are presented.

FIGS. 6A-6C illustrate a side-by-side comparison of various implementations of a heating filament having various geometries. FIG. 6A illustrates an implementation of a heating filament 602 having a longitudinal meandering line geometry. The heating filament 602 includes parallel segments 604 that are sequentially connected at opposite ends by connecting segments 606. The parallel segments 604 are arranged perpendicular to a longitudinal axis of a sample holder 608. FIG. 6B illustrates an implementation of a heating filament 612 having a transverse meandering line geometry. The heating filament 612 is similar in construction to the heating filament 402 described above with respect to FIG. 4. The heating filament 612 includes parallel segments 614, which are joined sequentially at opposite ends by perpendicular connecting segments 616, thereby giving the heating filament 402 a meandering shape. The parallel segments 614 are arranged parallel to a longitudinal axis of the sample holder 615. FIG. 6C illustrates an implementation of a sample heater 620 having an array of heating filaments 618. In the example shown in FIG. 6C, the heating filaments 618 have a tapered geometry; however, in other implementations, the heating filaments 618 may have a straight geometry, a longitudinal meandered line geometry, or a transverse meandered line geometry of the types illustrated in FIGS. 2-6B or other geometry. During operation, the array of heating filaments 618 increases a surface area of a sample holder 626 that is thermally coupled to the sample heater 620. In other implementations, the array of heating filaments 618 may also heat an array of sample containers. In various implementations, the heating filament 602, the heating filament 612, and the sample heater 620 may be used in conjunction with an electron magnetic resonance system such as the electron magnetic resonance system 100 described above relative to FIG. 1A.

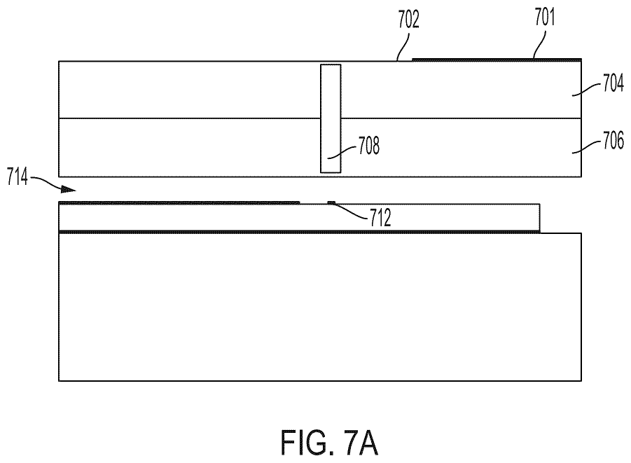

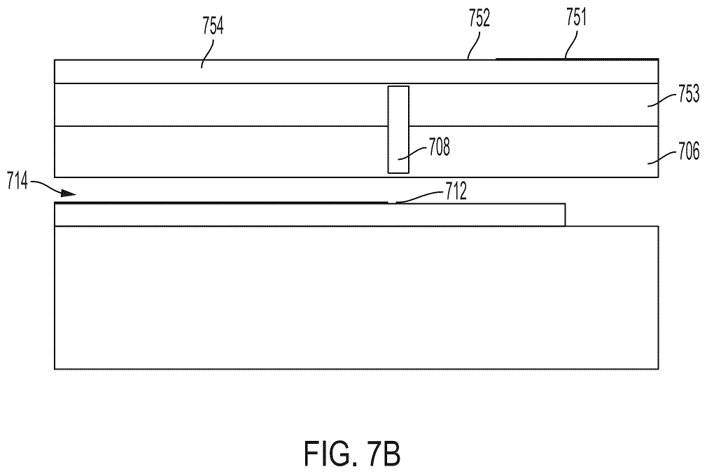

FIG. 7A is a cross-sectional view of an example resonator package. The heating filament 702 may be, for example, the heating filament 212, 302, 402, 602, 612, or 618 described above relative to FIGS. 2-6C. In various implementations, the heating filament 702 has a planar geometry and may be fabricated on a heater substrate 704 made of dielectric material. In some implementations, the heating filament 702 and the heater substrate 704 are placed on top of the sample holder 706 and make up a cover of the sample holder. The sample holder 706 is a dielectric slab with one or more of sample containers 708 that serve as a carrier and container for an electron magnetic resonance sample. In various implementations, the sample heater 701, along with the heater substrate 704, plays the role of a cover for the sample holder 706 in order to seal the electron magnetic resonance samples. As will be discussed below, in other implementations, the sample heater may be spaced apart from the sample holder. In still other implementations, the sample holder may comprise at least one microcapillary, which does not require a cover. In some implementations, the heater substrate 704 of the sample heater 701 can be the same as the dielectric material of the sample holder 706 and can be selected from any of the following: borosilicate glass, fused silica glass, fused quartz, sapphire, silicon, or any other dielectric material appropriate for electron magnetic resonance applications.

In addition, the heater substrate 704 and the sample holder 706 act as a medium to conduct heat from the heating filament 702, which is situated on the heater substrate 704, to the electron magnetic resonance sample in the sample holder 706, as seen in FIG. 7A In order to maintain a quality factor of the resonator 712 as high as possible, the heating filament 702 is located a distance 1) (shown in FIG. 2) from the electron magnetic resonance sample which is located directly above the resonator 712. Therefore, the thermal conductivity of the heater substrate 704 should be high enough to transfer heat to the electron magnetic resonance sample but not too high to dissipate energy without heating the sample. The thickness of the heater substrate 704, the thickness of the sample holder 706, the size of the sample container 708, and the height of the floor of the sample container 708 can be determined based on the spatial magnetic field profile of the resonator 712.

While transferring heat to the electron magnetic resonance sample to increase its temperature, a significant change in the temperature of the resonator 712 should be avoided, as such a temperature increase could cause a decline in a quality factor of the resonator 712 or otherwise degrade its performance and introduce thermal noise. To suppress heat transfer to the resonator 712, a thermal isolation layer 714 is used between the sample holder 706 and the resonator 712. In the example illustrated in FIG. 7A, a thermal isolation layer 714 may be a partial vacuum that is implemented to enhance thermal insulation. In various implementations, the partial vacuum is provided by the interior environment of the cryostat system. In various implementations, the thermal isolation layer 714 may be a region having a pressure of approximately 500 mTorr or less. In other implementations, other forms of thermal insulation could be utilized. In some instances, a low-thermal-conductivity material such as, for example, aero-gel, Teflon, fiberglass, or any other insulating material may be disposed in the thermal isolation layer 714.

In the example illustrated in FIG. 713, a sample heater 751 having a heating filament 752 is disposed on a heater substrate 754. A cover 753 is placed on top of the sample holder 706 and the heater substrate 754 is placed on top of the cover 753. Thus, in various implementations, the sample heater 751 and the heater substrate 754 need not be integral to the cover 753.

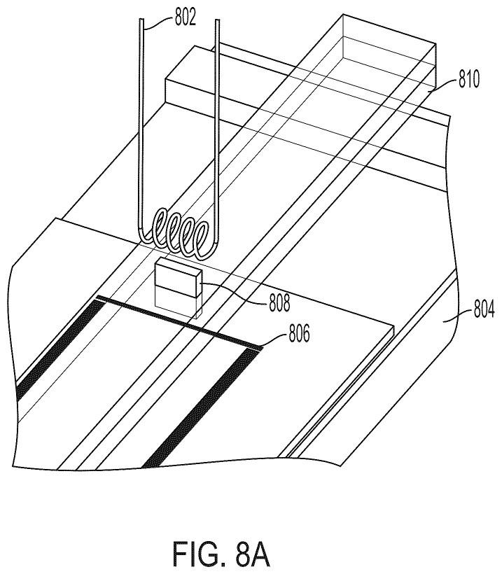

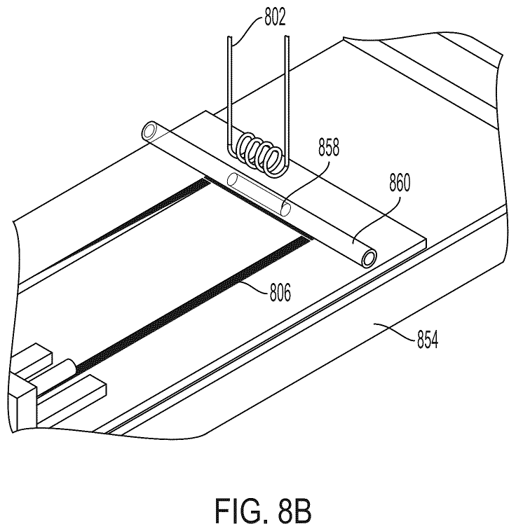

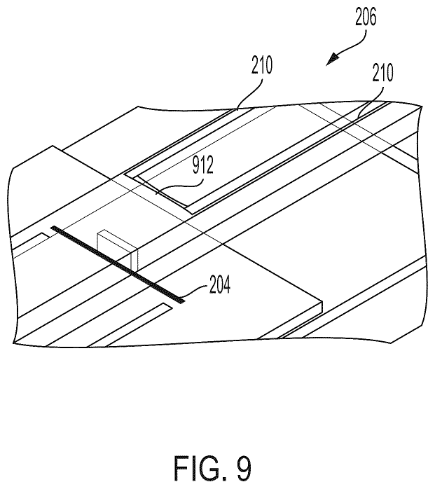

FIG. 8A is a perspective view of an example sample heater 802 that is contained in a resonator package 804. The resonator 806 is housed in the resonator package 804, which is constructed of a thermally and electrically conductive material such as, for example copper. In various implementations, the resonator package 804 may be used in an electron magnetic resonance system such as, for example, the electron magnetic resonance system 100 described above relative to FIG. 1A. The resonator 806 may be any type of resonator described above. During use, the resonator 806 is disposed in the resonator package. For clarity, an upper portion of the resonator package 804 is not shown in FIG. 8A. The sample heater 802 extends from an upper aspect of the resonator package 804 and is positioned such that a sample container 808 of the sample holder 810 is thermally coupled to the sample heater 802 when the sample container 808 is positioned in the sample region of the resonator 806. The sample heater 802 is illustrated by way of example in FIG. 8A as having a helical heating filament; however, in other implementations, the sample heater 802 may include any type of heating filament such as, for example, a straight filament, a tapered filament, a longitudinal meandering line filament, or a transverse meandering line filament, or other type of filament. Thus, the heating filament could be constructed similar to any of the heating filaments 212, 302, 402, 602, 612, or 618 described above relative to FIGS. 2-6C.

FIG. 8B is a perspective view of an example helical sample heater used with a tubular sample holder 860 and contained in a resonator package 854. The sample holder 860 is a tubular member such as, for example, a capillary or micro-capillary tube. In various implementations, the sample holder 860 does not utilize a cover. Similar to FIG. 8A, the sample heater 802 extends from an upper aspect of the resonator package 804 and is positioned such that a sample container 858 of the sample holder 860 is thermally coupled to the sample heater 802 when the sample container 858 is positioned in the sample region of the resonator 806. The sample heater 802 is illustrated by way of example in FIG. 8B as having a helical heating filament; however, in other implementations, the sample heater 802 may include any type of heating filament such as, for example, a straight filament, a tapered filament, a longitudinal meandering line filament, or a transverse meandering line filament, or other type of filament.

FIG. 9 is a perspective view of an example sample holder illustrating the sample heater 206 and the resonator 204. As described above with respect to FIG. 2, the sample heater 206 includes the first feedline 208 and the second feedline 210 that are electrically coupled to the heating filament 912. By way of example, the heating filament 912 is illustrated in FIG. 9 as being a tapered heating filament 912; however, in other implementations, the heating filament may include any type of heating filament such as, for example, a straight filament, a tapered filament, a longitudinal meandering line filament, or a transverse meandering line filament. Thus, the heating filament 912 could be constructed similar to any of the heating filaments 212, 302, 402, 602, 612, or 618 described above relative to FIGS. 2-6C. The first feedline 208 and the second feedline 210 supply electrical current to the heating filament 912. In various implementations, the first feedline 208 and the second feedline 210 have a width greater than a width of the heating filament 912 so as to decrease electrical resistance through the first feedline 208 and the second feedline 210.

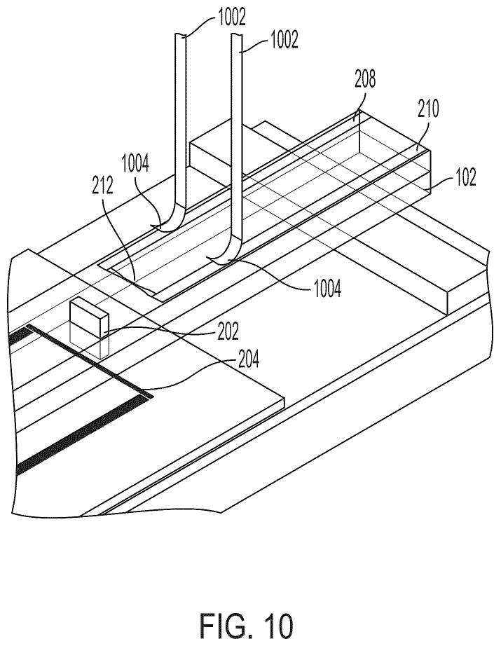

FIG. 10 is a perspective view of an example sample holder 102 illustrating an example electrical connection of the sample heater 206. Upon insertion of the sample container 202 into a resonator package (not shown for clarity), the first feedline 208 and the second feedline 210 contact a pair of electrical conductors 1002 that extend from an upper aspect of the resonator package such as, for example, the resonator package 804. In various implementations, the pair of electrical conductors 1002 are, for example, spring-loaded pins. In such an embodiment the pair of electrical conductors 1002 are biased against the first feedline 208 and the second feedline 210 by springs so as to maintain an electrical connection with the first feedline 208 and the second feedline 210. In the example illustrated in FIG. 10, the pair of electrical conductors 1002 include a curved spring segment 1004; however, in other implementations, the electrical conductors 1002 could utilize, for example, linear telescoping springs or any other arrangement to maintain electrical contact with the first feedline 208 and the second feedline 210.

The following paragraphs discuss simulations of example sample heaters and the impact of the example sample heaters on the performance of example resonators. While the simulations discussed below describe specific characteristics by way of example, one skilled in the art will recognize that the principles described below may be applied to any of the examples described herein.

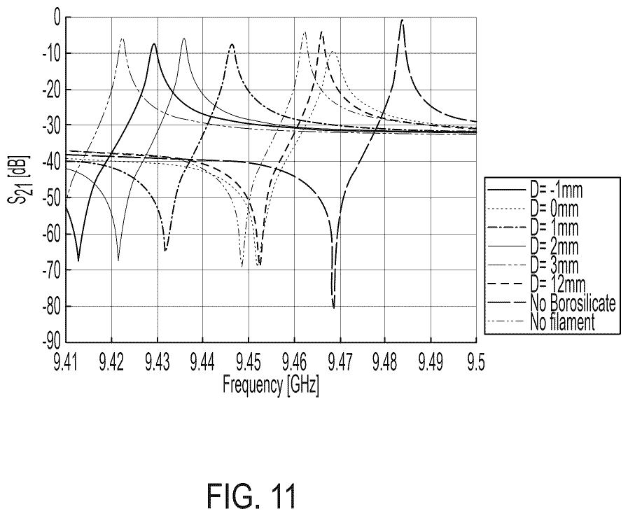

FIG. 11 illustrates simulated s-parameters of an example planar microstripline superconducting microwave resonator in the presence of a heating filament. The components described relative to FIGS. 11-16 could be any of the components described above relative to FIGS. 1-10. In particular, the heating filament discussed relative to FIGS. 11-16 could be any of the heating filaments described in FIGS. 2-6C. The data demonstrates that by positioning the heating filament at a lateral distance of D (shown in FIG. 2) away from the resonator, the quality factor and insertion loss of the device can be effectively preserved with minimal impact from the heating filament. The superconducting resonator is a versatile technology that can be implemented in a variety of ways, including, bit not limited to, microstriplines, coplanar waveguides (CPW), and lumped element planar resonators. Additionally, resonators may be arranged into an array. In the example shown in FIG. 11, the gap of the single microstripline resonator is 450 um, the thickness of the cartridge and the heating circuit's substrate both are 0.5 mm and they are made from borosilicate with dielectric constant 4.0472 and loss tangent 0.0022.

Table 1 presents calculated quality factors and insertion losses for various lateral locations of the heating filament. The data indicates that as the heating filament is placed closer to the resonator, both the Q factor and insertion loss deteriorate. This results in a substantial decline in resonator performance, highlighting the importance of proper placement of the heating filament in relation to the resonator. Additionally, a comparison of the simulation results for a bare resonator with and without a dielectric sample holder and heating substrate reveals that a significant amount of dielectric loss is introduced by the borosilicate materials. The data demonstrates that as the distance (D) between the heating filament and resonator increases, the resonator performance improves. Specifically, when the distance D=12 mm, the performance is comparable to the case where the heating filament is removed. When the distance D=−1 mm, the heating circuit passes through the resonator, shifting the heating filament closer to the microwave connectors.

| Configurations | Q | IL (dB) |
|---|---|---|
| Resonator only (no Borosilicate) | 17249 | −0.4788 |
| Resonator with Borosilicate (no heating Filament) | 10796 | −4.2305 |
| D = 12 mm (very far heating Filament) | 10774 | −4.2361 |
| D = 3 mm (after resonator) | 9972 | −5.2494 |
| D = 2 mm (after resonator) | 9238 | −5.6727 |
| D = 1 mm (after resonator) | 7218 | −7.5769 |
| D = −1 mm (before resonator) | 6984 | −7.2025 |
| D = 0 mm (on top of the resonator) | 5848 | −8.7675 |

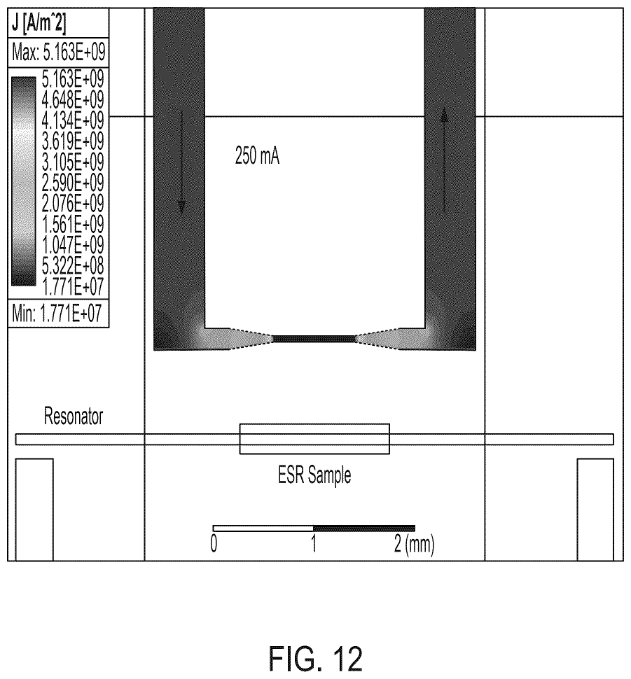

The electron magnetic resonance sample is heated by converting electrical energy into thermal energy through the resistive elements. FIG. 12 shows an overlay plot of the current density through the heating circuit. The plot illustrates that when a current of 250 mA is applied to the circuit, it results in a current density of 5×10⁹ A/m² in the heating filament. This results in a dissipated power of 0.0568 W in the filament and 0.0302 W in each feedline. The temperature of the electron magnetic resonance sample can be controlled by adjusting the input current and thereby the dissipated power. However, to ensure the effective functioning of the cryogenic system at its operating temperature (ambient temperature), the power input to the heating circuit should be regulated using, for example, the temperature controller 105 to remain within the bounds set by the cooling power capacity of the cryogenic system.

During operation, the resonator with the sample heater is placed within a cryogenic system, which can take the form of a continuous flow cryostat or a vacuum cryostat such as a closed loop cryogenic system, a He³ cryostat, a dilution refrigerator, or other type of cryosystem. To protect the resonator, which in various implementations is a resonator, from temperature increases caused by the sample heater, a thermal insulator layer is used as a thermal barrier between the resonator and the sample holder. In a vacuum cryostat, this layer is effectively provided by the partial vacuum that is created in the interior environment of the cryostat, eliminating the need for additional materials. In various implementations, the partial vacuum has a pressure of approximately 500 mTorr or less. However, it is also possible to use a continuous flow cryostat for a resonator with a sample heater. The cryostat environment is maintained at a base temperature of the system, for example 4 K (−269 C), which is maintained as the ambient temperature T∞ and the temperature for the external radiation for the resonator, sample heater and the microwave package.

In a cryostat with a partial vacuum space, the primary mode of heat transfer is through thermal conduction or thermal radiation, as there is no fluid present. However, in a continuous flow cryostat, all three modes of heat transfer—conduction, convection, and radiation—are present and can contribute to the overall heat transfer process.

Thermal performance of an example sample heater was simulated. Since a vacuum material is not acceptable for thermal analysis, a “near vacuum” medium was defined for the simulation. This material was modeled by the ideal gas equation of state PV=nRT where n is the number of moles of gas, R=8.31 J/K·mole is the universal gas constant, and P, V, and T are state variables of the gas—pressure, volume and temperature, respectively. The mass density can be determined using the equation

$$ρ = \frac{M P}{R T}$$

where M is the molar mass of the gas. For example, using this equation and the following data for the cryogenic system and dry air material of M=18.97 g/mole, P=2×10⁻⁶ Bar=0.2 Pa and T=4K, it is found that ρ=1.1414×10⁻⁴ Kg/m³ whereas the mass density of normal air at atmospheric pressure is ρ=1.1614 Kg/m³.

There are two principal specific heats, also known as heat capacity—defined for a fluid: one at constant volume (isochoric) denoted by Cᵥ and the other at constant pressure (isobaric) denoted by Cₚ. By utilizing Maxwell's equations of thermodynamics, the partial derivative of Cₚ (and Cᵥ) with respect to pressure (and volume) at a constant temperature can be calculated using the following equations.

$${( \frac{\partial {C}_{p}}{\partial P} )}_{T} = - T {( \frac{{\partial }^{2} V}{\partial {T}^{2}} )}_{P} \qquad ( Eq . 1 )$$

$${( \frac{\partial {C}_{v}}{\partial V} )}_{T} = T {( \frac{{\partial }^{2} P}{\partial {T}^{2}} )}_{V} \qquad ( Eq . 2 )$$

By substituting the ideal gas equation of state of PV=nRT into the previous equations,

$${( \frac{{\partial }^{2} V}{\partial {T}^{2}} )}_{P} = 0 and {( \frac{{\partial }^{2} P}{\partial {T}^{2}} )}_{v} = 0$$

is obtained. Therefore, for an ideal gas, the heat capacity does not depend on pressure (or volume) and is only a function of temperature, as seen in the equations

$${( \frac{\partial {C}_{p}}{\partial P} )}_{T} = 0 and {( \frac{\partial {C}_{v}}{\partial V} )}_{T} = 0 .$$

Thus, the same heat capacity for the “near vacuum” material as for normal air, i.e. Cₚ=1000 J/Kg·K and Cᵥ=720 J/KgK may be used.

The thermal conductivity of the absolute vacuum is zero, as there are no atomic vibrations to transfer heat energy. The thermal conductivity of air versus pressure is plotted and a low value of κ=0.000261 W/m·K was selected.

The governing equation for conduction heat transfer is

$$ρ {C}_{p} \frac{\partial T}{\partial t} = ∇ \cdot ( \vec{k} ∇ T ) + {q}^{′′′} \qquad ( Eq . 3 )$$

In the above equations, T is temperature, q′″ is the volumetric heat source density (W/m³), \vec{k} is the thermal conductivity tensor for non-isotropic or heterogenous materials, Cₚ is the specific heat capacity and ρ is the mass density. This equation is the result of combining the Fourier's law of heat conduction \vec{q″}=−κ∇T, where

$${q}^{″} = \frac{\dot{Q}}{A}$$

is the heat flux rate per unit area (W/m²), the conservation of energy

$$- \frac{{dq}^{′′′}}{d t} = ∇ {q}^{″}$$

which is the first law of thermodynamics (for a source free region), and the specific heat capacity definition ΔQ=mCₚΔT where Q is the heat energy. For isotropic media with no heat source, this equation can be simplified to the normal heat diffusion equation in the form of

$$ρ {C}_{p} \frac{\partial T}{\partial t} = κ {∇}^{2} T$$

where the right-hand side is the diffusion heat (or conduction heat) and the left-hand side represents the accumulation heat (or storage heat). The parameter

$$α = \frac{κ}{ρ {C}_{p}}$$

is called thermal diffusivity and is a measure of the ratio of diffusion heat to storage heat. Additionally, for the case of transient conduction, the time constant for the temperature change is estimated to be

$$τ = \frac{( Δ {x}^{2} )}{α}$$

where Δx is the length of the heat conduction. For steady-state (∂T/∂t=0) heat transfer over a material with the uniaxial thermal conductivity, the partial differential equation expressing thermal equilibrium is:

$$\frac{\partial }{\partial x} ( {κ}_{x x} \frac{\partial T}{\partial x} ) + \frac{\partial }{\partial y} ( {κ}_{y y} \frac{\partial T}{\partial y} ) + \frac{\partial }{\partial z} ( {κ}_{Z Z} \frac{\partial T}{\partial z} ) + {q}^{′′′} = 0 \qquad ( Eq . 4 )$$

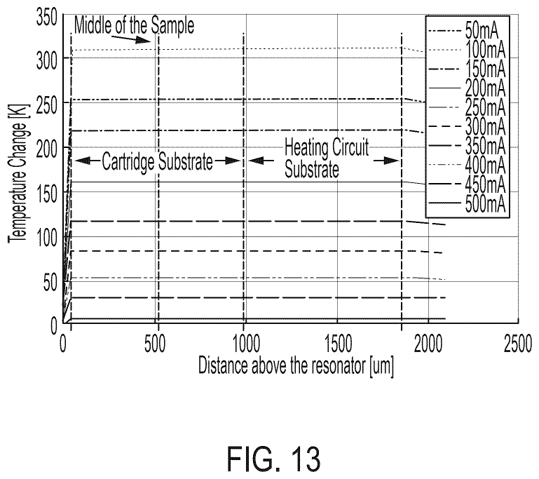

When an electrical heat generator with flowing current I and resistance R is present, a quick 1D approximation for estimating the temperature increase is

$$Δ T ∼ \frac{{RI}^{2} Δ x}{κ A} \qquad ( Eq . 5 )$$

where κ is the thermal conductivity of the medium, A is the cross-sectional area of the heat transfer and Δx (denoted as L in the following sentences) is the length scale over which the heat conduction occurs. For example, if the borosilicate glass is used with a thermal conductivity κ=1.14891 W/mK, length scale Δx=2 mm, cross section A=0.8 mm×1.8 mm, I=150 mA and R=0.9Ω, the estimated temperature would be ΔT˜24.47 K which is close to the plot in FIG. 13.

In this case, the time constant can be calculated using the equation τ=L²/α=ρCₚL²/κ. If the specific heat capacity of Borosilicate is used as Cₚ=799.744 J/(Kg·K) and the mass density as ρ=2124.85 Kg/m³ we find that τ˜5.9 s.

Another contribution to heat transfer in our device and platform is the thermal radiation. Radiation is a highly nonlinear mode of heat transfer. A simplified form of the equation describing radiation from one surface to another surface (surface-to-surface) is

$${Q}_{i \to j} = \frac{σ ( {T}_{i}^{4} - {T}_{j}^{4} )}{\frac{1 - {ϵ}_{i}}{{A}_{i} {ϵ}_{i}} + \frac{1}{{A}_{i} {F}_{ij}} + \frac{1 - {ϵ}_{j}}{{A}_{j} {ϵ}_{j}}} \qquad ( Eq . 6 )$$

where Aᵢ is the surface area, ∈ᵢ is the emissivity of the surface which determines the amount of thermal radiation emitted, σ=5.67×10⁻⁸W/m²K⁴ is the Stefan-Boltzmann constant and the Fᵢⱼ is the view factor between the surfaces defined as the fraction of total radiant energy that leaves surface i at temperature Tᵢ[K] which arrives directly on surface j at temperature Tⱼ[K] with the following relation

$${F}_{i j} = \frac{1}{{A}_{i}} {\int }_{{A}_{j}} {\int }_{{A}_{i}} \frac{cos {θ}_{i} cos {θ}_{j}}{π {s}^{2}} d {A}_{j} d {A}_{i} \qquad ( Eq . 7 )$$

In Equation 7, s represents the distance between the infinitesimal area dAᵢ on surface i and infinitesimal area dAⱼ on surface j. The angle θᵢ(or θⱼ) is the angle between the normal line on surface i (or surface j) at position dAᵢ (or dAⱼ) and the line connected dAᵢ to dAⱼ.

The surface-to-surface formulation equation is a cost-effective approach for accounting for thermal radiation in geometrically simple surfaces. However, it is limited by several assumptions, including that surfaces are gray (emissivity equals absorptivity and is independent of wavelength) and opaque (transmissivity is neglected) to thermal radiation, diffuse in nature (reflectivity is independent of incoming direction), and do not account for medium-related absorption, re-emission, and scattering. A more advanced approach is the “ray tracing” radiation model, in which simple surfaces are replaced by clusters of cell surfaces.

The general equation of radiation heat transfer in an absorbing, emitting, and anisotropically scattering medium can be described by the integrodifferential radiative transfer equation as

$$\hat{s} ∇ I ( r , \hat{s} ) = κ ( r ) {I}_{b} ( r ) - β ( r ) I ( r , \hat{s} ) + \frac{{σ}_{s} ( r )}{4 π} {\int }_{4 π} I ( r , \hat{s} ) Φ ( r , {\hat{s}}^{′} , \hat{s} ) d {Ω}^{′} \qquad ( Eq . 8 )$$

where I and I_{b} are the intensity of radiation and the blackbody intensity, respectively, and σₛ, κ, and β are scattering, absorption and extinction coefficients. The scattering phase function, ϕ, is represented in units of [Sr⁻¹]. This model is effective for complex geometries with many participating surfaces and is considered a more conservative approach. The first term on the right-hand side represents emission, the second term represents absorption, and the third term represents scattering in the medium which expressed by integral over solid angels. Due to the complexity of the equation and its associated boundary conditions, the “discrete ordinates” method or the Sn method is employed to solve the problem approximately. This model was used in the simulation to account for radiation heat transfer.

In heat transfer through convection, fluid motion is involved to transfer heat. The convection model is usually the most efficient way to transfer heat in liquids and gases. This involves both heat conduction through surfaces and transport of heat to/from surfaces via fluid advection. The velocity field has a significant impact on the heat transfer rate, so accurate prediction of fluid flow is crucial for accurate heat transfer prediction. The simple equation for heat transfer in convection is described by Newton's law of cooling with the heat transfer coefficient h

$${q}^{″} = h ( T - {T}_{∞} ) \qquad ( Eq . 9 )$$

In more complex situations, the convection model is described by a combination of the continuity equation (conservation of mass), momentum equation (Navier-Stoke equation) and energy equation (temperature distribution):

$$∇ \cdot V = 0 \qquad ( Eq . 10 )$$

$$ρ ( \frac{\partial V}{\partial t} + V \cdot ∇ V ) = - ∇ p + ∇ τ - ρ g \qquad ( Eq . 11 )$$

$$ρ {C}_{p} ( \frac{\partial T}{\partial t} + V \cdot ∇ T ) = ∇ \cdot ( \vec{k} ∇ T ) + {q}^{′′′} \qquad ( Eq . 12 )$$

where, V, ρ, τ and g are velocity vector, pressure, stress tensor and gravity vector, respectively. In the simulation, the convection model was not used as the example device was in a vacuum cryostat.

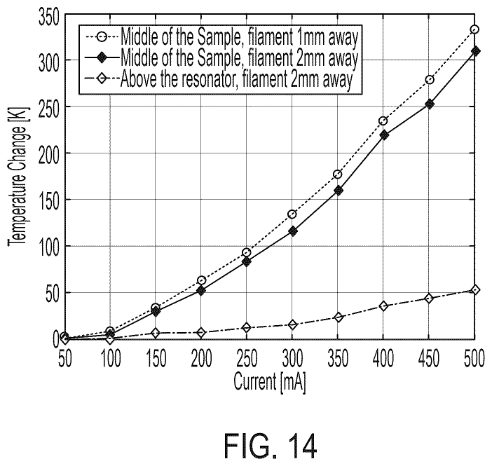

FIG. 13 is a plot illustrating a temperature profile along a line perpendicular to the sample holder plotted against the varying current flowing through the heating filament. The line begins at the resonator and passes through all Borosilicate material. The heating filament is located 2 mm away laterally from both the resonator and the sample. In FIG. 13, the leftmost sections of the temperature profiles are due to thermal radiation. These sections are enlarged and displayed in FIG. 14 for closer examination. In all simulations, the emissivity of all surfaces was assumed to be ∈=0.8.

FIG. 14 illustrates the temperature rise profile plotted against the current when the heating filament is positioned 1 mm and 2 mm away laterally from the middle of the sample. Additionally, the temperature rise just above the resonator is displayed and is found to be significantly lower than the temperature rise in the sample.

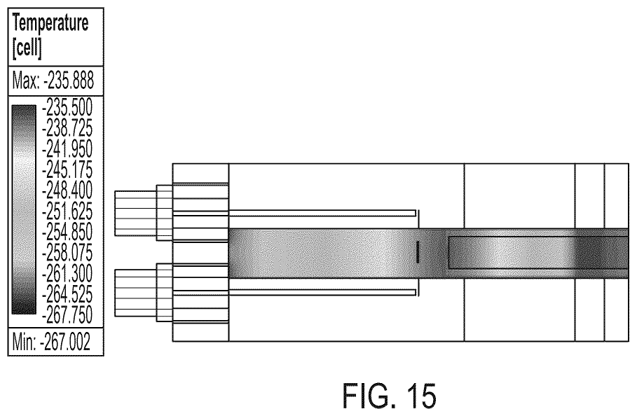

FIG. 15 illustrates the temperature field overlay (in Celsius) on the bottom surface of the sample holder when the current of 150 mA is flowing over the heating element which is 2 mm away from the sample.

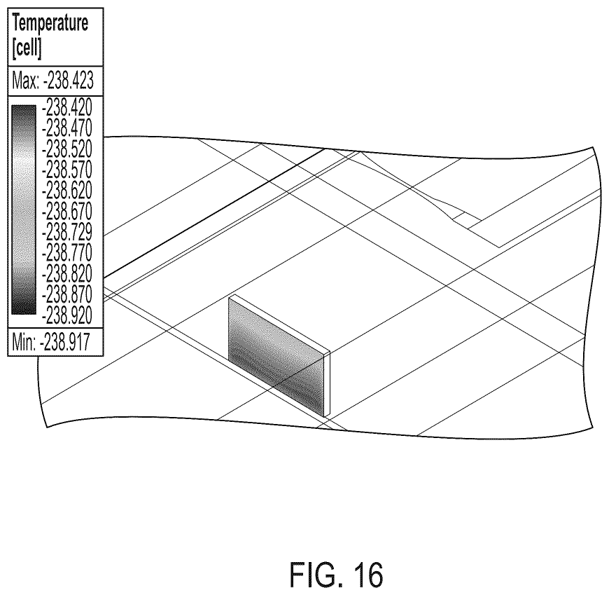

FIG. 16 illustrates the temperature field overlay (in Celsius) over the sample volume when the current of 150 mA is flowing over the heating element which is 2 mm away from the sample. The temperature variation across the sample volume is less than 0.5K.

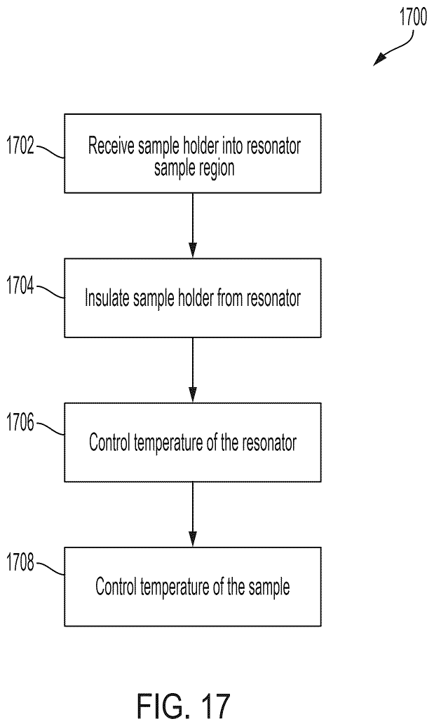

FIG. 17 is a flow diagram illustrating a process 1700 for heating samples in a electron magnetic resonance system. In various implementations, the electron magnetic resonance system is the example electron magnetic resonance system 100 discussed above with respect to FIG. 1A, or another type of electron magnetic resonance system. The example process 1700 may include additional or different operations, and the operations may be performed in the order shown or in another order. In some cases, one or more operations may be repeated, omitted, or performed in another manner.

At 1702, a sample holder is received into a sample region of a resonator. The sample holder can be, for example, the example sample holder 102 shown in FIG. 1A, any of the example sample holders described above and shown in FIGS. 2-10, or another type of sample holder. The resonator operates in a primary magnetic field of a primary magnet system. The resonator package may be disposed in a cryogenic thermal environment controlled by a cooling system. The sample holder is thermally coupled to a sample heater. The sample heater may be, for example, the sample heater 104 shown in FIG. 1A, any of the example sample heaters shown in FIGS. 2-10, or another type of sample heater. In various implementations the sample heater includes a heating filament that is disposed between two feedlines. The feedlines are coupled to an electrical power source through, for example, a pair of spring-biased pins or another arrangement.

At 1704, the sample holder and the sample heater are thermally insulated from the resonator. In various implementations, the thermal insulation may be a partial vacuum layer having for example, a pressure of approximately 500 mTorr or less that is created by the cryo-system. In some implementations, the partial vacuum layer may be the thermal isolation layer 714. In other implementations, the thermal insulation may be a fluid or solid layer. In some instances, the thermal insulation is a low-thermal-conductivity material such as, for example, aero-gel, Teflon, fiberglass, or any other insulating material.

At 1706, the temperature of the resonator is controlled. In various implementations, the temperature of the resonator is controlled using the cryo-system. In implementations where the resonator is a super-conducting resonator, the temperature is controlled to a temperature below the resonator's critical temperature.

At 1708, a temperature of the sample is controlled using the sample heater. In various embodiments, the temperature of the sample is controlled by supplying a current to the feedlines and the heating filament of the sample heater. In various implementations, the temperature of the sample is controlled by applying an electrical current to a sample heater. The sample heater may be any of the sample heaters described in FIGS. 1-11 or another type of sample heater. In various implementations, the temperature is controlled using, for example, the temperature controller 105. Temperature control of the sample may, in various implementations, be open-loop control or closed-loop control. In implementations employing open-loop control, a current is applied to the sample heater that corresponds to a desired temperature. In implementations utilizing closed-loop control, feedback information such as, for example, sample temperature or relaxation time (T₁ and T₂) may be utilized. In various implementations, measurements of temperature-dependent spin dynamics such as, for example, spin signal amplitude, relaxation time (T₁ and T₂) measurements, or any other temperature dependent spin signal may be measured as a proxy for sample temperature thereby allowing closed-loop control of the sample heater while eliminating the need for a temperature sensor near the electron magnetic resonance sample.

In a first example, the present disclosure relates to an electron magnetic resonance apparatus. The electron magnetic resonance apparatus includes a microwave resonator disposed in a cryogenic environment. A sample holder is disposed in the cryogenic environment with the microwave resonator. The sample holder includes a sample container that is thermally insulated from the microwave resonator and holds a sample in a sample region of the microwave resonator. A sample heating device is thermally coupled to the sample container and is configured to control a temperature of the sample above a temperature of the resonator.

In various implementations of the first example, the apparatus may include a heater substrate that is in thermal contact with the sample holder. In various implementations of the first example, the sample heating device may reside in mechanical contact with the sample holder. In other implementations, the sample heating device may be spaced apart from the sample holder.

In various implementations of the first example, the sample heating device may include a heating filament that is electrically coupled to a pair of electrical feedlines. A temperature controller may be coupled to the pair of electrical feedlines through a pair of spring biased pins. In various implementations, the heating filament may be a resistive heating filament and may be one of a straight filament, a tapered heating filament, a longitudinal meandered line, or a transverse meandered line.

In various implementations of the first example, the apparatus may include a temperature controller that is configured to control a temperature of the sample heating device based on a temperature of the sample. In such implementations, the sample holder may include a temperature sensor that is configured to measure a temperature of the sample.

In various implementations of the first example, the microwave resonator may include a superconducting material and be configured to operate below a critical temperature of the superconducting material.

In various implementations of the first example, the sample heating device may include an array of heating filaments.

In various implementations of the first example, the sample container may be thermally insulated from the resonator by a thermal insulator material disposed between the resonator and the sample holder. In other implementations, the sample container may be thermally insulated from the resonator by a partial vacuum region disposed between the resonator and the sample holder.

In various implementations of the first example, the sample holder and the sample heating device may be disposed in a cryogenic system that includes a temperature control system that sets the temperature of the resonator to a first cryogenic temperature.

In various implementations of the first example, the sample holder may be configured to operate in a primary magnetic field of a probeless magnetic resonance system. In other implementations, the sample holder may be configured to operate on a probe in a primary magnetic field of a magnetic resonance system.

In a second example, aspects of the disclosure relate to an electron magnetic resonance system. The electron magnetic resonance system includes a primary magnet system configured to generate a primary magnetic field and a cryogenic system. A microwave resonator is disposed in the cryogenic system. The microwave resonator is configured to operate in the primary magnetic field and to interact with a sample in a sample region. A sample holder includes a sample container that is thermally insulated from the resonator and that holds the sample in the sample region. A sample heating device is thermally coupled to the sample container and is configured to control a temperature of the sample above a temperature of the microwave resonator.

Various implementations of the second example include the features and variations described above with respect to the first example.

In a third example, the present disclosure relates to an electron magnetic resonance method. The method includes positioning a sample in a sample region of a resonator disposed in a primary magnetic field of an electron magnetic resonance system. The sample is thermally insulated from the resonator. By operation of a cryogenic system, a temperature of the resonator is controlled to be in a cryogenic temperature range. By operation of a sample heating system, a temperature of the sample is controlled to be in a temperature range above the temperature of the resonator. By operation of the resonator, a control field is applied to the sample in the sample region.

In various implementations of the third example, the sample holder includes a sample container that holds the sample and the method includes positioning the sample heating system in thermal contact with the sample holder.

In various implementations of the third example, the sample heating system includes a heating filament that is electrically coupled to a pair of electrical feedlines, and controlling the temperature of the sample includes delivering electrical current to the heating filament.

In various implementations of the third example, the method may include measuring a temperature of the sample and controlling the temperature of the sample based on the measured temperature of the sample. In various implementations the temperature of the sample may be measured by operation of a temperature sensor.

In various implementations of the third example, the method may include obtaining spin signals from the sample by operation of the resonator and measuring the temperature of the sample based on a temperature-dependent property of the spin signals.

In various implementations of the third example, the sample holder may include a sample container that holds the sample and the method may include thermally insulating the sample container from the resonator by a thermal insulator material disposed between the resonator and the sample holder. In other implementations, the method may include thermally insulating the sample container from the resonator by a partial vacuum region disposed between the resonator and the sample holder.

In a fourth example, the present disclosure relates to a sample heating device for an electron magnetic resonance system. The sample heating device includes a substrate, a first feedline disposed on the substrate, and a second feedline disposed on the substrate. A heating filament is electrically coupled to the first feedline and the second feedline. A temperature control unit is electrically coupled to the heating filament via the first feedline and the second feedline. A sample holder includes a sample container that is thermally coupled to the heating filament. The sample container is thermally insulated from a microwave resonator that operates in a cryogenic environment.

Various implementations of the fourth example include the features and variations described above with respect to the first example.

While this specification contains many details, these should not be understood as limitations on the scope of what may be claimed, but rather as descriptions of features specific to particular examples. Certain features that are described in this specification or shown in the drawings in the context of separate implementations can also be combined. Conversely, various features that are described or shown in the context of a single implementation can also be implemented in multiple embodiments separately or in any suitable subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the principles described program components and systems can generally be integrated together in a single product or packaged into multiple products.

A number of embodiments have been described. Nevertheless, it will be understood that various modifications can be made. For example, in various implementations, a guide system may be utilized to facilitate insertion and placement of the sample holder within the resonator package and to prevent breakage of the sample holder. Such a guide system may include, for example rails, that support opposite edges of the sample holder during placement. Accordingly, other embodiments are within the scope of the following claims.

1. An electron magnetic resonance apparatus, comprising:
a microwave resonator disposed in a cryogenic environment;
a sample holder disposed in the cryogenic environment with the microwave resonator, wherein the sample holder comprises a sample container that is thermally insulated from the microwave resonator and holds a sample in a sample region of the microwave resonator; and
a sample heating device that is thermally coupled to the sample container and configured to control a temperature of the sample above a temperature of the resonator.

2. The apparatus of claim 1, wherein the sample heating device comprises a heater substrate that is in thermal contact with the sample holder.

3. The apparatus of claim 1, wherein the sample heating device resides in mechanical contact with the sample holder.

4. The apparatus of claim 1, wherein the sample heating device is spaced apart from the sample holder.

5. The apparatus of claim 1, wherein the sample heating device comprises a heating filament that is electrically coupled to a pair of electrical feedlines.

6. The apparatus of claim 5, comprising a temperature controller that is coupled to the pair of electrical feedlines through a pair of spring biased pins.

7. The apparatus of claim 5, wherein the heating filament comprises a resistive heating element.

8. The apparatus of claim 7, wherein the heating filament is one of a straight filament, a tapered heating filament, a longitudinal meandered line, and a transverse meandered line.

9. The apparatus of claim 1, comprising a temperature controller configured to control a temperature of the sample heating device based on the temperature of the sample.

10. The apparatus of claim 9, wherein the sample holder comprises a temperature sensor configured to measure the temperature of the sample.

11. The apparatus of claim 1, wherein the microwave resonator comprises a superconducting material, and the microwave resonator is configured to operate below a critical temperature of the superconducting material.

12. The apparatus of claim 1, wherein the sample heating device comprises an array of heating filaments.

13. The apparatus of claim 1, wherein the sample container is thermally insulated from the resonator by a thermal insulator material disposed between the resonator and the sample holder.

14. The apparatus of claim 1, wherein the sample container is thermally insulated from the resonator by a partial vacuum region disposed between the resonator and the sample holder.

15. The apparatus of claim 1, wherein the sample holder and the sample heating device are disposed in a cryogenic system comprising a temperature control system that sets the temperature of the resonator to a first cryogenic temperature.

16. The apparatus of claim 1, wherein the sample holder is configured to operate in a primary magnetic field of a probeless magnetic resonance system.

17. The apparatus of claim 1, wherein the sample holder is configured to operate on a probe in a primary magnetic field of a magnetic resonance system.

18. An electron magnetic resonance system comprising:
a primary magnet system configured to generate a primary magnetic field;
a cryogenic system;
a microwave resonator disposed in the cryogenic system, wherein the microwave resonator is configured to operate in the primary magnetic field and to interact with a sample in a sample region;
a sample holder comprising a sample container that is thermally insulated from the resonator and holds the sample in the sample region; and
a sample heating device that is thermally coupled to the sample container and configured to control a temperature of the sample above a temperature of the microwave resonator.

19. The system of claim 18, wherein the sample heating device comprises a heater substrate that is in thermal contact with the sample holder.

20. The system of claim 18, wherein the sample heating device resides in mechanical contact with the sample holder.

21. The system of claim 18, wherein the sample heating device is spaced apart from the sample holder.

22. The system of claim 18, wherein the sample heating device comprises a heating filament that is electrically coupled to a pair of electrical feedlines.

23. The system of claim 22, comprising a temperature controller that is coupled to the pair of electrical feedlines through a pair of spring biased pins.

24. The system of claim 22, wherein the heating filament comprises a resistive heating element.

25. The system of claim 24, wherein the heating filament is one of a straight filament, a tapered heating filament, a longitudinal meandered line, and a transverse meandered line.

26. The system of claim 18, comprising a temperature controller configured to control a temperature of the sample heating device based on the temperature of the sample.

27. The system of claim 26, wherein the sample holder comprises a temperature sensor configured to measure the temperature of the sample.

28. The system of claim 18, wherein the microwave resonator comprises a superconducting material, and the microwave resonator is configured to operate below a critical temperature of the superconducting material.

29. The system of claim 18, wherein the sample heating device comprises an array of heating filaments.

30. The system of claim 18, wherein the sample container is thermally insulated from the resonator by a thermal insulator material disposed between the resonator and the sample holder.

31. The system of claim 18, wherein the sample container is thermally insulated from the resonator by a partial vacuum region disposed between the resonator and the sample holder.

32. The system of claim 18, wherein:
the sample holder and the sample heating device are disposed in the cryogenic system; and
the cryogenic system comprises a temperature control system that sets the temperature of the resonator to a first cryogenic temperature.

33. An electron magnetic resonance method, comprising:
positioning a sample in a sample region of a resonator disposed in a primary magnetic field of an electron magnetic resonance system;
thermally insulating the sample from the resonator;
by operation of a cryogenic system, controlling a temperature of the resonator to be in a cryogenic temperature range;
by operation of a sample heating system, controlling a temperature of the sample to be in a temperature range above the temperature of the resonator; and
by operation of the resonator, applying a control field to the sample in the sample region.

34. The method of claim 33, wherein a sample holder comprises a sample container that holds the sample, and the method comprises positioning the sample heating system in thermal contact with the sample holder.

35. The method of claim 33, wherein the sample heating system comprises a heating filament that is electrically coupled to a pair of electrical feedlines, and controlling the temperature of the sample comprises delivering electrical current to the heating filament.

36. The method of claim 33, comprising:
measuring the temperature of the sample; and
controlling the temperature of the sample based on the measured temperature of the sample.

37. The method of claim 36, comprising measuring the temperature of the sample by operation of a temperature sensor.

38. The method of claim 36, comprising:
by operation of the resonator, obtaining spin signals from the sample; and
measuring the temperature of the sample based on a temperature-dependent property of the spin signals.

39. The method of claim 33, wherein a sample holder comprises a sample container that holds the sample, and the method comprises thermally insulating the sample container from the resonator by a thermal insulator material disposed between the resonator and the sample holder.

40. The method of claim 33, wherein a sample holder comprises a sample container that holds the sample, and the method comprises thermally insulating the sample container from the resonator by a partial vacuum region disposed between the resonator and the sample holder.
